(19) United States
(12) Patent Application Publication
(10) Pub. No.: US 2023/0223746 A1
(43) Pub. Date: Jul. 13, 2023

(54) CLAMPER, INPUT CIRCUIT, AND SEMICONDUCTOR DEVICE

(71) Applicant: ROHM Co., LTD., Kyoto (JP)

(72) Inventors: Adrian Joita, Kyoto (JP); Toru TAKUMA, Kyoto (JP); Shuntaro Takahashi, Kyoto (JP)

(21) Appl. No.: 18/151,538

(22) Filed: Jan. 9, 2023

(30) Foreign Application Priority Data
Jan. 12, 2022 (JP) 2022-003101

(51) Int. Cl. H02H 3/08; H02H 7/20

(52) U.S. Cl. CPC H02H 3/08; H02H 7/205

(57) ABSTRACT

Disclosed herein is a clamper including a current source that is connected between an external electrode and an internal node and generates a predetermined constant current, a diode having an anode connected to the internal node, and a current mirror that generates a second current corresponding to a first current flowing via the diode and draws the second current from the internal node to a reference voltage node.

### CROSS REFERENCE TO RELATED APPLICATIONS

This application claims priority benefit of Japanese Patent Application No. JP 2022-003101 filed in the Japan Patent Office on Jan. 12, 2022. Each of the above-referenced applications is hereby incorporated herein by reference in its entirety.

### BACKGROUND

The technology disclosed in the present specification relates to a clamper, an input circuit, and a semiconductor device.

The applicant has proposed so far a number of new technologies related to a semiconductor device such as an on-vehicle intelligent power device (IPD) (see, for example, WO2017/187785).

### SUMMARY

However, an input circuit used in a related-art semiconductor device has room for improvement in coping with low voltage driving.

In particular, in recent years, an on-vehicle integrated circuit (IC) is demanded to comply with ISO26262 (an international standard for functional safety related to automotive electrical and electronic systems), and more highly reliable design is important also for an on-vehicle IPD.

Accordingly, it is desirable to provide a clamper, an input circuit, and a semiconductor device capable of coping with low voltage driving.

According to an embodiment of the present technology, there is provided a clamper including a current source that is connected between an external electrode and an internal node and generates a predetermined constant current, a diode having an anode connected to the internal node, and a current mirror that generates a second current corresponding to a first current flowing via the diode and draws the second current from the internal node to a reference voltage node.

According to another embodiment of the present technology, there is provided a clamper including a first current source that is connected between an internal node and a reference voltage node and generates a predetermined sink current, a second current source that is connected between a power supply voltage node and the internal node and generates a predetermined source current smaller than the sink current, a diode having an anode connected to the power supply voltage node, and a current mirror that generates a second current corresponding to a first current flowing via the diode and causes the second current to flow from the power supply voltage node to the internal node.

According to a further embodiment of the present technology, there is provided an input circuit including a transistor having a gate connected to a first internal node and a drain connected to a second internal node, a first clamper that limits a potential difference between the first internal node and a reference voltage node to a first clamp voltage or less, and a second clamper that limits a potential difference between a power supply voltage node and the second internal node to a second clamp voltage or less. The first clamper includes a current source that is connected between an external electrode and the first internal node and generates a predetermined constant current, a first diode having an anode connected to the first internal node, and a first current mirror that generates a second current corresponding to a first current flowing via the first diode and draws the second current from the first internal node to the reference voltage node. The second clamper includes a first current source that is connected between the second internal node and the reference voltage node and generates a predetermined sink current, a second current source that is connected between the power supply voltage node and the second internal node and generates a predetermined source current smaller than the sink current, a second diode having an anode connected to the power supply voltage node, and a second current mirror that generates a fourth current corresponding to a third current flowing via the second diode and causes the fourth current to flow from the power supply voltage node to the second internal node.

It should be noted that other features, elements, steps, advantages, and characteristics will further be clarified by the following embodiments and the accompanying drawings related thereto.

According to the embodiments of the technology disclosed in the present specification, it is possible to provide a clamper, an input circuit, and a semiconductor device capable of coping with low voltage driving.

### BRIEF DESCRIPTION OF THE DRAWINGS

FIG. 1 is a diagram depicting a configuration example of an electronic apparatus including a semiconductor device;

FIG. 2 is a block circuit diagram depicting an electrical structure of the semiconductor device;

FIG. 3 is a diagram depicting a comparative example of an input circuit;

FIG. 4 is a diagram depicting an input circuit according to a first embodiment;

FIG. 5 is a diagram depicting an operation example of the first embodiment;

FIG. 6 is a diagram depicting an input circuit according to a second embodiment;

FIG. 7 is a diagram depicting an operation example of the second embodiment; and

FIG. 8 is an external view depicting a configuration example of a vehicle.

### DETAILED DESCRIPTION OF THE PREFERRED EMBODIMENTS

### <Electronic Apparatus>

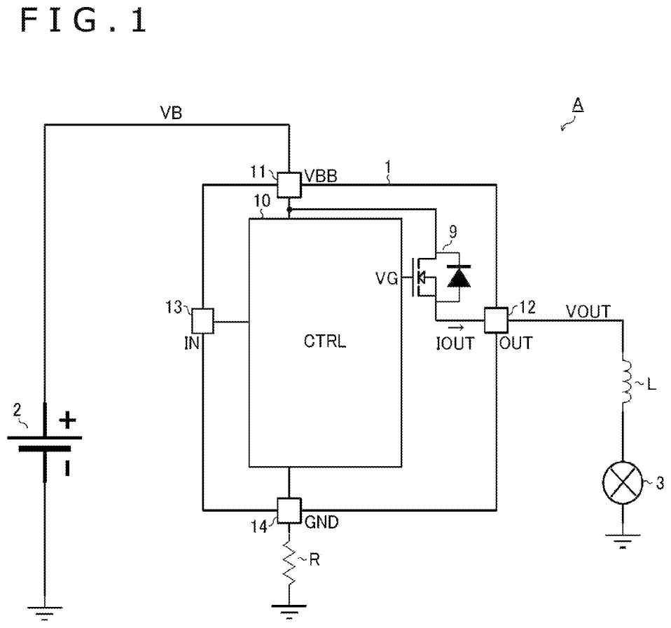

FIG. 1 is a diagram depicting a configuration example of an electronic apparatus including a semiconductor device. An electronic apparatus A of the configuration example includes a semiconductor device 1, a direct-current (DC) power supply 2, and a load 3.

The semiconductor device 1 is a high-side switch IC (a kind of IPD) for electrically connecting and disconnecting the DC power supply 2 and the load 3 to and from each other, and is formed by integrating a power metal insulator semiconductor field effect transistor (MISFET) 9 and a controller 10.

In addition, the semiconductor device 1 includes a plurality of external electrodes as sections for establishing electrical connection with an outside of the device. Referring to the drawing, the semiconductor device 1 includes a drain electrode 11 (corresponding to a power supply electrode VBB), a source electrode 12 (corresponding to an output electrode OUT), an input electrode 13 (corresponding to an input electrode IN), and a reference voltage electrode 14 (corresponding to a ground electrode GND).

The power MISFET 9 is an example of an insulated gate-type power transistor (output transistor) and functions as a high-side switch element for electrically connecting and disconnecting the drain electrode 11 and the source electrode 12 to and from each other.

The controller 10 includes a plurality of kinds of functional circuits for realizing various functions. For example, the plurality of kinds of functional circuits includes a circuit that generates a gate control signal VG for driving and controlling the power MISFET 9 on the basis of an electric signal from the outside.

The drain electrode 11 transmits a power supply voltage VB to a drain of the power MISFET 9 and various circuits of the controller 10. The source electrode 12 is connected to a source of the power MISFET 9 and transmits an output voltage VOUT and an output current IOUT to the load 3. It should be noted that a signal line (for example, a wire harness) laid between the source electrode 12 and the load 3 is generally accompanied by an inductance component L (and a resistance component). The input electrode 13 transmits an input voltage (input signal IN) for driving the controller 10. The reference voltage electrode 14 transmits a reference voltage (for example, a ground voltage) to the controller 10. It should be noted that a portion between the reference voltage electrode 14 and a ground terminal is generally accompanied by a resistance component R.

### <Semiconductor Device (Electrical Structure)>

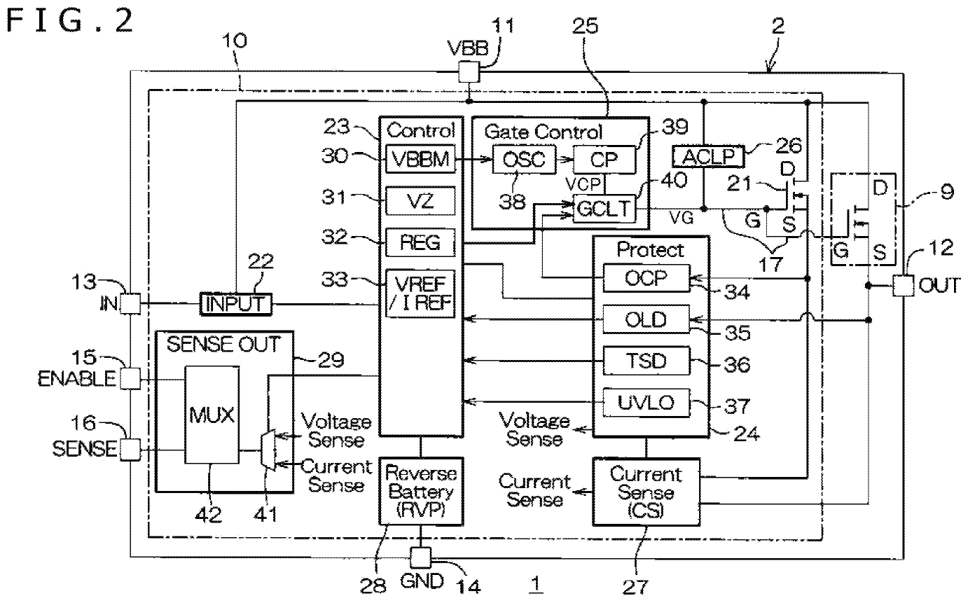

FIG. 2 is a block circuit diagram depicting an electrical structure of the semiconductor device 1 depicted in FIG. 1. Hereinafter, a case where the semiconductor device 1 is mounted on a vehicle will be described as an example. It should be noted that, when being mounted on a vehicle, the semiconductor device 1 may be applied as a high-side switch for controlling energization of a light source such as a valve lamp or a light emitting diode (LED) lamp or other types of electronic control devices.

The semiconductor device 1 includes the drain electrode 11, the source electrode 12, the input electrode 13, the reference voltage electrode 14, an enable electrode 15, a sense electrode 16, a gate control wiring 17, the power MISFET 9, and the controller 10.

The drain electrode 11 (power supply electrode VBB) is connected to the DC power supply 2. The drain electrode 11 provides the power supply voltage VB to the power MISFET 9 and the controller 10. The power supply voltage VB may be 10 V or more but 20 V or less. Meanwhile, the source electrode 12 (output electrode OUT) is connected to the load 3.

The input electrode 13 (input electrode IN) may be connected to a micro controller unit (MCU), a DC/DC converter, or a low drop out (LDO) regulator, for example. The input electrode 13 provides an input voltage to the controller 10. The input voltage may be 1 V or more but 10 V or less. The reference voltage electrode 14 is connected to a reference voltage wiring (ground terminal). The reference voltage electrode 14 provides a reference voltage to the power MISFET 9 and the controller 10.

The enable electrode 15 may be connected to the MCU. An electric signal for enabling or disabling some or all of the functions of the controller 10 is input to the enable electrode 15. The sense electrode 16 transmits an electric signal for detecting an abnormality of the controller 10 to the outside of the device. It should be noted that the sense electrode 16 may be pulled up or down by a resistor.

A gate of the power MISFET 9 is connected to the controller 10 (a gate control circuit 25 to be described later) via the gate control wiring 17. The drain of the power MISFET 9 is connected to the drain electrode 11. The source of the power MISFET 9 is connected to the controller 10 (a current detection circuit 27 to be described later) and the source electrode 12.

The controller 10 includes a sensor MISFET 21, an input circuit 22, a current/voltage control circuit 23, a protection circuit 24, the gate control circuit 25, an active clamp circuit 26, the current detection circuit 27, a power supply reverse connection protection circuit 28, and an abnormality detection circuit 29.

A gate of the sensor MISFET 21 is connected to the gate control circuit 25. A drain of the sensor MISFET 21 is connected to the drain electrode 11. A source of the sensor MISFET 21 is connected to the current detection circuit 27.

The input circuit 22 is connected to the input electrode 13 and the current/voltage control circuit 23. The input circuit 22 may include a Schmitt trigger circuit. The input circuit 22 shapes a waveform of an electric signal applied to the input electrode 13. A signal generated by the input circuit 22 is input to the current/voltage control circuit 23.

The current/voltage control circuit 23 is connected to the protection circuit 24, the gate control circuit 25, the power supply reverse connection protection circuit 28, and the abnormality detection circuit 29. The current/voltage control circuit 23 may include a logic circuit.

The current/voltage control circuit 23 generates various voltages according to electric signals from the input circuit 22 and electric signals from the protection circuit 24. In this configuration, the current/voltage control circuit 23 includes a driving voltage generation circuit 30, a first constant voltage generation circuit 31, a second constant voltage generation circuit 32, and a reference voltage/reference current generation circuit 33.

The driving voltage generation circuit 30 generates a driving voltage for driving the gate control circuit 25. The driving voltage may be set to a value obtained by subtracting a predetermined value from the power supply voltage VB. The driving voltage generation circuit 30 may generate a driving voltage of 5 V or more but 15 V or less obtained by subtracting 5 V from the power supply voltage VB. The driving voltage is input to the gate control circuit 25.

The first constant voltage generation circuit 31 generates a first constant voltage for driving the protection circuit 24. The first constant voltage generation circuit 31 may include a Zener diode or a regulator circuit (here, a Zener diode). The first constant voltage may be 1 V or more but 5 V or less. The first constant voltage is input to the protection circuit 24 (more specifically, a load open detection circuit 35 or other circuits to be described later).

The second constant voltage generation circuit 32 generates a second constant voltage for driving the protection circuit 24. The second constant voltage generation circuit 32 may include a Zener diode or a regulator circuit (here, a regulator circuit). The second constant voltage may be 1 V or more but 5 V or less. The second constant voltage is input to the protection circuit 24 (more specifically, an overheat protection circuit 36 and a low voltage malfunction suppression circuit 37 to be described later).

The reference voltage/reference current generation circuit 33 generates a reference voltage and a reference current for various circuits. The reference voltage may be 1 V or more but 5 V or less. The reference current may be 1 mA or more but 1 A or less. The reference voltage and the reference current are input to various circuits. In the case where the various circuits include a comparator, the reference voltage and the reference current may be input to the comparator.

The protection circuit 24 is connected to the current/voltage control circuit 23, the gate control circuit 25, the abnormality detection circuit 29, the source of the power MISFET 9, and the source of the sensor MISFET 21. The protection circuit 24 includes an overcurrent protection circuit 34, the load open detection circuit 35, the overheat protection circuit 36, and the low voltage malfunction suppression circuit 37.

The overcurrent protection circuit 34 protects the power MISFET 9 from an overcurrent. The overcurrent protection circuit 34 is connected to the gate control circuit 25 and the source of the sensor MISFET 21. The overcurrent protection circuit 34 may include a current monitoring circuit. A signal generated by the overcurrent protection circuit 34 is input to the gate control circuit 25 (more specifically, a gate control signal output circuit 40 to be described later).

The load open detection circuit 35 detects a short-circuit state and an open state of the power MISFET 9. The load open detection circuit 35 is connected to the current/voltage control circuit 23 and the source of the power MISFET 9. A signal generated by the load open detection circuit 35 is input to the current/voltage control circuit 23.

The overheat protection circuit 36 monitors a temperature of the power MISFET 9 and protects the power MISFET 9 from an excessive temperature rise. The overheat protection circuit 36 is connected to the current/voltage control circuit 23. The overheat protection circuit 36 may include a temperature sensitive device such as a temperature sensitive diode or a thermistor. A signal generated by the overheat protection circuit 36 is input to the current/voltage control circuit 23.

The low voltage malfunction suppression circuit 37 suppresses malfunction of the power MISFET 9 when the power supply voltage VB is less than a predetermined value. The low voltage malfunction suppression circuit 37 is connected to the current/voltage control circuit 23. A signal generated by the low voltage malfunction suppression circuit 37 is input to the current/voltage control circuit 23.

The gate control circuit 25 controls an ON state and an OFF state of the power MISFET 9 and an ON state and an OFF state of the sensor MISFET 21. The gate control circuit 25 is connected to the current/voltage control circuit 23, the protection circuit 24, the gate of the power MISFET 9, and the gate of the sensor MISFET 21.

The gate control circuit 25 outputs a gate control signal VG to the gate control wiring 17 according to an electric signal from the current/voltage control circuit 23 and an electric signal from the protection circuit 24. The gate control signal VG is input to each of the gate of the power MISFET 9 and the gate of the sensor MISFET 21 via the gate control wiring 17. Specifically, the gate control circuit 25 turns on/off the power MISFET 9 by controlling the gate control signal VG according to an electric signal (input signal) applied to the input electrode 13.

The gate control circuit 25 includes, more specifically, an oscillation circuit 38, a charge pump circuit 39, and the gate control signal output circuit 40. The oscillation circuit 38 oscillates according to an electric signal from the current/voltage control circuit 23 to generate a predetermined electric signal. The electric signal generated by the oscillation circuit 38 is input to the charge pump circuit 39. The charge pump circuit 39 generates a boosted voltage VCP on the basis of the electric signal from the oscillation circuit 38. The boosted voltage VCP generated by the charge pump circuit 39 is input to the gate control signal output circuit 40. It should be noted that the charge pump circuit 39 is an example of a boosted voltage generation circuit.

The gate control signal output circuit 40 operates in response to the boosted voltage VCP output from the charge pump circuit 39 and generates the gate control signal VG according to the electric signal from the protection circuit 24 (more specifically, the overcurrent protection circuit 34). The gate control signal VG is input to the gate of the power MISFET 9 and the gate of the sensor MISFET 21 via the gate control wiring 17. The sensor MISFET 21 and the power MISFET 9 are simultaneously controlled by the gate control circuit 25.

The active clamp circuit 26 protects the power MISFET 9 from a counter electromotive force. The active clamp circuit 26 is connected to the drain electrode 11, the gate of the power MISFET 9, and the gate of the sensor MISFET 21. The active clamp circuit 26 may include a plurality of diodes.

The active clamp circuit 26 may include a plurality of diodes connected in forward bias to each other. The active clamp circuit 26 may include a plurality of diodes connected in reverse bias to each other. The active clamp circuit 26 may include a plurality of diodes connected in forward bias to each other and a plurality of diodes connected in reverse bias to each other.

The plurality of diodes may include a pn junction diode or a Zener diode or may include a pn junction diode and a Zener diode. The active clamp circuit 26 may include a plurality of Zener diodes bias-connected to each other. The active clamp circuit 26 may include a Zener diode and a pn junction diode connected in reverse bias to each other.

The current detection circuit 27 detects a current flowing through the power MISFET 9 and the sensor MISFET 21. The current detection circuit 27 is connected to the protection circuit 24, the abnormality detection circuit 29, the source of the power MISFET 9, and the source of the sensor MISFET 21. The current detection circuit 27 generates a current detection signal according to an electric signal (output current IOUT) generated by the power MISFET 9 and an electric signal (a sense current exhibiting the same behavior as the output current IOUT) generated by the sensor MISFET 21. The current detection signal is input to the abnormality detection circuit 29.

The power supply reverse connection protection circuit 28 protects the current/voltage control circuit 23, the power MISFET 9, and other elements from a reverse voltage when the DC power supply 2 is reversely connected. The power supply reverse connection protection circuit 28 is connected to the reference voltage electrode 14 and the current/voltage control circuit 23.

The abnormality detection circuit 29 monitors a voltage of the protection circuit 24. The abnormality detection circuit 29 is connected to the current/voltage control circuit 23, the protection circuit 24, and the current detection circuit 27. In the case where any of the overcurrent protection circuit 34, the load open detection circuit 35, the overheat protection circuit 36, and the low voltage malfunction suppression circuit 37 is abnormal (voltage fluctuation, for example), the abnormality detection circuit 29 generates an abnormality detection signal according to the voltage of the protection circuit 24 and outputs the generated abnormality detection signal to the outside.

The abnormality detection circuit 29 includes, more specifically, a first multiplexer circuit 41 and a second multiplexer circuit 42. The first multiplexer circuit 41 includes two input units, one output unit, and one selection control input unit. The protection circuit 24 and the current detection circuit 27 are connected to the respective input units of the first multiplexer circuit 41. The second multiplexer circuit 42 is connected to the output unit of the first multiplexer circuit 41. The current/voltage control circuit 23 is connected to the selection control input unit of the first multiplexer circuit 41.

The first multiplexer circuit 41 generates an abnormality detection signal according to an electric signal from the current/voltage control circuit 23, a voltage detection signal from the protection circuit 24, and a current detection signal from the current detection circuit 27. The abnormality detection signal generated by the first multiplexer circuit 41 is input to the second multiplexer circuit 42.

The second multiplexer circuit 42 includes two input units and one output unit. The output unit of the first multiplexer circuit 41 and the enable electrode 15 are connected to the respective input units of the second multiplexer circuit 42. The sense electrode 16 is connected to the output unit of the second multiplexer circuit 42.

In the case where the MCU is connected to the enable electrode 15 and a resistor for pull-up or pull-down is connected to the sense electrode 16, an ON signal is input from the MCU to the enable electrode 15, and the abnormality detection signal is extracted from the sense electrode 16. The abnormality detection signal is converted into an electric signal by the resistor connected to the sense electrode 16. A state abnormality of the semiconductor device 1 is detected on the basis of the electric signal.

### <Input Circuit (Comparative Example)>

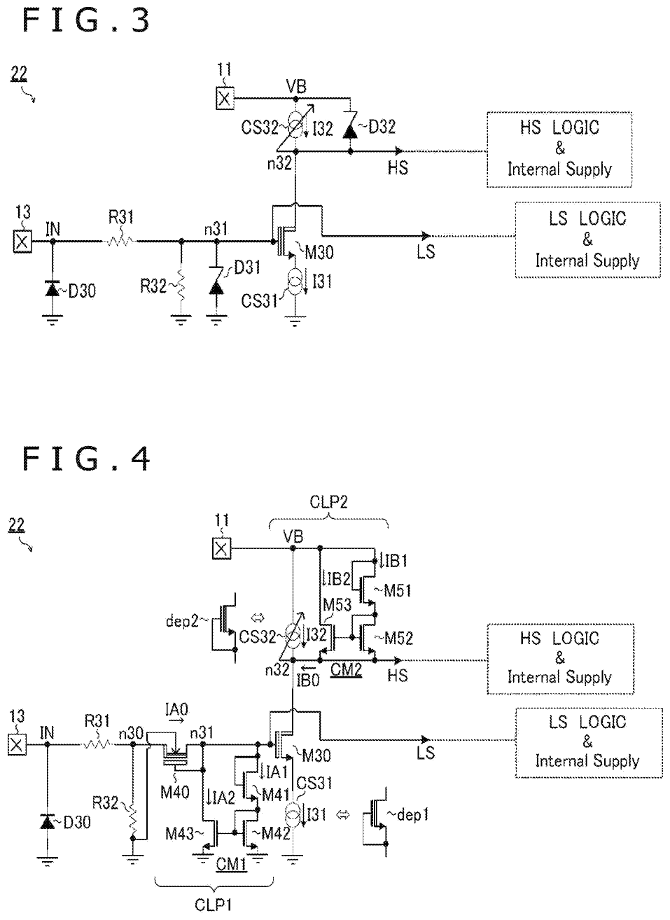

FIG. 3 is a diagram depicting a comparative example (a general circuit configuration to be compared with the embodiment to be described below) of the input circuit 22. The input circuit 22 of the comparative example is a typical example of a level shifter that receives an input of an input signal IN (for example, 7 V/GND domain) applied to the input electrode 13 and outputs an output signal LS (for example, 5 V/GND domain) to a low-side logic and an output signal HS (for example, VB/VB−5 V domain) to a high-side logic.

Referring to the drawing, the input circuit 22 of the comparative example includes a transistor M30 (for example, a high breakdown voltage N-channel MISFET), a diode D30, Zener diodes D31 and D32, resistors R31 and R32, and current sources CS31 and CS32.

The resistor R31 is connected between the input electrode 13 and an internal node n31. The resistor R31 thus connected functions as an electrostatic discharge (ESD) protection element (current limiting element). The resistor R31 may be set to, for example, substantially 1 kΩ.

The resistor R32 is connected between the internal node n31 and a reference voltage node (for example, a ground terminal). The resistor R32 thus connected functions as a pull-down element for fixing the internal node n31 to a low level when the input electrode 13 is in an open state. The resistor R32 may be set to, for example, substantially 100 kΩ.

A cathode of the diode D30 is connected to the input electrode 13. An anode of the diode D30 is connected to a reference voltage node (for example, a ground terminal). The diode D30 thus connected functions as a first ESD protection element.

A cathode of the Zener diode D31 is connected to the internal node n31. An anode of the Zener diode D31 is connected to a reference voltage node (for example, a ground terminal). The Zener diode D31 thus connected functions as a second ESD protection element and also functions as a first clamp element that limits a potential difference between the internal node n31 and the reference voltage node (for example, the ground terminal) to a first clamp voltage Vclp1 or less. Therefore, a high level of the output signal LS appearing at the internal node n31 is limited to the first clamp voltage Vclp1 or less (for example, 5 V or less). It should be noted that the output signal LS is also used as an internal power supply.

A gate of the transistor M30 (for example, an N-channel MISFET) is connected to the internal node n31. A drain of the transistor M30 is connected to an internal node n32. A source of the transistor M30 is connected to the current source CS31. The transistor M30 is turned on when the internal node n31 is at a high level (for example, 5 V) and turned off when the internal node n31 is at a low level (for example, 0 V). It should be noted that, as the transistor M30, a high breakdown voltage element that can withstand application of the power supply voltage VB may be used.

The current source CS31 (corresponding to a first current source) is connected between the source of the transistor M30 and a reference voltage node (for example, a ground terminal) and generates a predetermined sink current 131. It should be noted that the sink current 131 may be set to a current value (at least two times or more) larger than a source current 132 to be described below.

The current source CS32 (corresponding to a second current source) is connected between a power supply voltage node (the drain electrode 11 to which the power supply voltage VB is applied) and the internal node n32, and generates the predetermined source current 132 smaller than the sink current 131.

It should be noted that the current source CS32 may switch a magnitude of the source current 132 according to the output signal HS appearing at the internal node n32. For example, the current source CS32 may include a plurality of unit current sources and may switch the number of drives of unit current sources according to the output signal HS. With such a configuration, hysteresis can be added to a threshold at which a logic level of the output signal HS is switched.

A cathode of the Zener diode D32 is connected to the power supply voltage node (the drain electrode 11 to which the power supply voltage VB is applied). An anode of the Zener diode D32 is connected to the internal node n32. The Zener diode D32 thus connected also functions as a second clamp element for limiting a potential difference between the power supply voltage node and the internal node n31 to a second clamp voltage Vclp2 or less in cooperation with the current sources CS31 and CS32. Therefore, a low level of the output signal HS appearing at the internal node n32 is limited to a voltage value, which is obtained by subtracting the second clamp voltage Vclp2 from the power supply voltage VB, or more (for example, VB−5 V or more). It should be noted that the output signal HS is also used as an internal power supply.

### <Consideration on Low Voltage Driving>

An N-channel MISFET has an on-resistance that is substantially two to three times as excellent as that of a P-channel MISFET having the same element area (the on-resistance is low). In view of this, the N-channel MISFET is preferentially used as the power MISFET 9 (output transistor). However, in order to completely turn on the N-channel MISFET, it may be necessary to apply a positive gate-source voltage to the N-channel MISFET. Accordingly, a boosted voltage generation circuit for generating the boosted voltage VCP higher than the power supply voltage VB, for example, the charge pump circuit 39, which is relatively inexpensive, is often incorporated in the semiconductor device 1. In particular, in the IPD handling a large current and a high voltage, the charge pump circuit 39 and other floating power supply circuits are integrated, and the power MISFET 9 having a vertical structure is appropriately controlled.

Incidentally, in the semiconductor device 1, a low breakdown voltage device (for example, a breakdown voltage of 5 V) and a high breakdown voltage device (for example, a breakdown voltage of 40 V) are combined and monolithically mounted. If a high breakdown voltage device is used, voltage robustness of the semiconductor device 1 can be improved. However, in view of cost reduction of the entire system, it is desirable to use low breakdown voltage devices as much as possible by minimizing use of high breakdown voltage devices.

In this regard, the input circuit 22 of the comparative example (FIG. 3) is extremely high in robustness, and the voltage robustness of the semiconductor device 1 can be enhanced while minimizing the use of high breakdown voltage devices.

In recent years, however, due to advances in technologies and processes, provision of an ultra-low breakdown voltage device (for example, a breakdown voltage of 3 V) has begun to replace the related-art low breakdown voltage device (for example, a breakdown voltage of 5 V). In order to maintain consistency and compatibility with existing products while mounting such an ultra-low breakdown voltage device (for example, a breakdown voltage of 3 V) in the semiconductor device 1, it may be necessary to limit a voltage applied to the ultra-low breakdown voltage device to the breakdown voltage thereof or less (for example, 3 V or less) after receiving an input signal IN of 0 to 5 V (or a voltage higher than that).

However, in the input circuit 22 of the comparative example (FIG. 3), it is difficult to set the first clamp voltage Vclp1 and the second clamp voltage Vclp2 described above to 3 V or less. This is because the Zener diodes D31 and D32 are each a pn junction diode realized at a junction between a p-type semiconductor region and an n-type semiconductor region, and it is very difficult to design the breakdown voltage of each of them to 3 V or less. For example, the breakdown voltage of a Zener diode set by a doping profile used in a general manufacturing process is substantially 5 to 6 V, and it is extremely difficult to lower it to 3 V or less.

It should be noted that, as a section for solving the above problem, for example, a configuration in which a voltage applied to the ultra-low breakdown voltage device is clamped by a pre-regulator that is typically turned on by receiving the supply of the power supply voltage VB is conceivable. However, in such a solving method, it may be necessary to additionally mount the pre-regulator, and thus, the circuit area and current consumption increase.

In the following, in view of the above consideration, a new embodiment that can cope with ultra-low voltage driving (for example, 3 V driving) while suppressing an increase in circuit area and current consumption is proposed.

### <Input Circuit (First Embodiment)>

FIG. 4 is a diagram depicting an input circuit 22 according to a first embodiment. The input circuit 22 of the present embodiment includes clampers CLP1 and CLP2 in place of the Zener diodes D31 and D32 on the basis of the comparative example (FIG. 3) described above. Accordingly, the constitutional elements described above are denoted by the same reference symbols as those in FIG. 3 to omit the duplicated description, and the following description will focus on characteristic parts of the present embodiment.

The clamper CLP1 includes a transistor M40 (for example, a depletion N-channel MISFET having a negative on-threshold voltage) and transistors M41 to M43 (for example, N-channel MISFETs).

A drain of the transistor M40 is connected to an internal node n30 (a connection node between the resistors R31 and R32). Both a gate and a source of the transistor M40 are connected to the internal node n31. A back gate of the transistor M40 is connected to a reference voltage node (for example, a ground terminal).

As described above, the depletion-type transistor M40 configured to short-circuit between the gate and the source is connected between the input electrode 13 (an example of an external electrode) and the internal node n31 and functions as a current source configured to generate a predetermined constant current IA0. In other words, the transistor M40 can also be understood as a current source configured to limit the maximum current flowing through the clamper CLP1. It should be noted that, as the transistor M40, a high breakdown voltage element that can withstand a potential difference between the power supply voltage node and the reference voltage node may be used.

Both a gate and a drain of the transistor M41 are connected to the internal node n31. The transistor M41 thus diode-connected functions as a first diode having its anode connected to the internal node n31. It should be noted that a diode element may be used in place of the transistor M41. In addition, in place of the single transistor M41, a plurality of diode-connected transistors or a plurality of diode elements connected in series to each other may be used.

Each of sources of the transistors M42 and M43 is connected to a reference voltage node (for example, a ground terminal). Both of gates of the transistors M42 and M43 are connected to a drain of the transistor M42. The drain of the transistor M42 is connected to a source (a cathode of the first diode) of the diode-connected transistor M41. A drain of the transistor M43 is connected to the internal node n31.

The transistors M42 and M43 thus connected function as a current mirror CM1 (corresponding to a first current mirror) that generates a second current IA2 by mirroring a first current IA1 flowing through the drain of the transistor M42 via the diode-connected transistor M41 (corresponding to the first diode), and that draws the second current IA2 flowing through the drain of the transistor M43, from the internal node n31 to the reference voltage node.

It should be noted that, while details of the operation will be described later, the clamper CLP1 of the present configuration example functions as a first clamper configured to limit the potential difference between the internal node n31 and the reference voltage node (for example, the ground terminal) to the first clamp voltage Vclp1 or less (for example, 3 V or less).

The clamper CLP2 includes the above-described current sources CS31 and CS32, and transistors M51 to M53 (for example, N-channel MISFETs).

As described above, the current source CS31 (corresponding to the first current source) is connected between the source of the transistor M30 and the reference voltage node (for example, the ground terminal) and generates the predetermined sink current 131. It should be noted that the sink current 131 may be set to a current value (at least two times or more) larger than a source current 132 to be described below.

As described above, the current source CS32 (corresponding to the second current source) is connected between the power supply voltage node (the drain electrode 11 to which the power supply voltage VB is applied) and the internal node n32, and generates the predetermined source current 132 smaller than the sink current 131.

It should be noted that the current sources CS31 and CS32 can be mounted by using depletion-type transistors dep1 and dep2 (for example, depletion N-channel MISFETs) each configured to short-circuit between its gate and source as depicted in the drawing.

Both a gate and a drain of the transistor M51 are connected to the power supply voltage node (the drain electrode 11 to which the power supply voltage VB is applied). The transistor M51 thus diode-connected functions as a second diode having its anode connected to the power supply voltage node. It should be noted that a diode element may be used in place of the transistor M51. In addition, in place of the single transistor M51, a plurality of diode-connected transistors or a plurality of diode elements connected in series to each other may be used.

Both of sources of the transistors M52 and M53 are connected to the internal node n32. Both of gates of the transistors M52 and M53 are connected to a drain of the transistor M52. The drain of the transistor M52 is connected to a source (a cathode of the second diode) of the diode-connected transistor M51. A drain of the transistor M53 is connected to the power supply voltage node.

The transistors M52 and M53 thus connected function as a current mirror CM2 (corresponding to a second current mirror) that generates a fourth current IB2 by mirroring a third current IB1 flowing through the drain of the transistor M52 via the diode-connected transistor M51 (corresponding to the second diode), and that causes the fourth current IB2 flowing through the drain of the transistor M53 to flow from the power supply voltage node to the internal node n32.

It should be noted that, while details of the operation will be described later, the clamper CLP2 of the present configuration example functions as a second clamper configured to limit the potential difference between the power supply voltage node (the drain electrode 11 to which the power supply voltage VB is applied) and the internal node n32 to the second clamp voltage Vclp2 or less (for example, 3 V or less).

Next, the operation of the input circuit 22 in the present embodiment will be described. First, the operation of the clamper CLP1 is focused on. When the input signal IN applied to the input electrode 13 is at a low level (for example, 0 V), the applied voltage of the internal node n30 (the drain voltage of the transistor M40) decreases, and the applied voltage of the internal node n31 (the gate voltage of the transistor M30) also decreases.

Specifically describing with reference to the drawing, there is a pull-down path via the transistor M40 and the resistor R32 between the gate of the transistor M30 and the reference voltage node (for example, the ground end). Therefore, when the input signal IN is at a low level (substantially 0 V), the output signal LS appearing at the internal node n31 also becomes a low level (substantially 0 V).

On the other hand, when the input signal IN is at a high level (for example, 5 V), the applied voltage of the internal node n30 (the drain voltage of the transistor M40) rises up to a voltage value (near 5 V) defined by a resistance ratio between the resistors R31 and R32.

Here, the transistor M40 is an N-channel MISFET in which a body (back gate) is connected to the reference voltage node (for example, the ground terminal). In addition, the transistor M40 is of a depletion type having a negative on-threshold voltage. Therefore, the transistor M40 configured to short-circuit between its gate and source functions as a current source that is typically turned on.

A source potential of the transistor M40 rises toward a drain potential of the transistor M40. However, since a body potential of the transistor M40 is fixed, a substrate bias effect of the transistor M40 works. Accordingly, an effective threshold of the transistor M40 rises, and the channel disappears. It should be noted that the effective threshold of the transistor M40 is substantially 3 V.

The transistors M41 to M43 protect a gate oxide of the transistor M30 and function as clampers for correcting variations in the substrate bias effect of the transistor M40. The transistors M41 and M42 are connected in series as metal oxide semiconductor (MOS) diodes between the internal node n31 and the reference voltage node (for example, the ground terminal). In addition, the transistors M42 and M43 operate as the current mirror CM1 as described above.

When the constant current IA0 output from the transistor M40 starts to flow through the transistors M41 and M42 as the first current IA1, the transistor M43 pulls out the second current IA2 (α×IA1) corresponding to a mirror ratio α of the current mirror CM1 from the internal node n31 toward the reference voltage node (for example, the ground terminal). As a result, the first current IA1 becomes a differential current (IA0−IA2) obtained by subtracting the second current IA2 from the constant current IA0.

By such a negative feedback action, the first current IA1 flowing through the transistors M41 and M42 is regulated to a current value for clamping the output signal LS appearing at the internal node n31 to an appropriate level.

It should be noted that, in the case where the number of stages of the MOS diodes connected in series between the internal node n31 and the reference voltage node (for example, the ground terminal) is m (m=2 in the drawing) and each gate-source voltage is Vgs, Vclp1=m×Vgs is established.

The first current IA1 (IA0/(1+α)) flowing through the transistors M41 and M42 depends on the constant current IA0 flowing through the transistor M40 and the mirror ratio α of the current mirror CM1. Here, the drain current (constant current IA0) of the depletion-type transistor M40 has positive temperature characteristics. That is, the constant current IA0 increases as the temperature increases, and decreases as the temperature decreases. On the other hand, the gate-source voltages Vgs of the enhancement-type transistors M41 and M42 have negative temperature characteristics. That is, the gate-source voltage Vgs decreases as the temperature increases, and increases as the temperature decreases.

Therefore, by adjusting sizes of the respective transistors M40 to M43 and appropriately selecting the mirror ratio α of the current mirror CM1, it is possible to realize the first clamp voltage Vclp1 (for example, 3 V) independent of the temperature.

Next, the operation of the clamper CLP2 (and a level shifter including the transistor M30) is focused on. When the input signal IN applied to the input electrode 13 is at a low level (for example, 0 V), the internal node n31 becomes a low level (for example, 0 V) as described above. Therefore, the transistor M30 is turned off. At this time, the current source CS31 operates in a triode region (also referred to as a linear region or an unsaturated region). Therefore, the internal node n32 is raised to a high level (substantially VB) by the current source CS32.

On the other hand, when the input signal IN is at a high level (for example, 5 V or 7 V), the internal node n31 becomes a high level (for example, 3 V). Therefore, since the transistor M30 is turned on, the sink current 131 flows via the transistor M30. As described above, the sink current 131 generated by the current source C31 is larger than the source current 132 generated by the current source C32. Therefore, the internal node n32 decreases toward a low level (substantially 0 V).

The transistors M51 and M52 are connected in series as MOS diodes between the power supply voltage node (the drain electrode 11 to which the power supply voltage VB is applied) and the internal node n32. In addition, the transistors M52 and M53 operate as the current mirror CM2 as described above.

When the transistor M30 is turned on and a constant current IB0 (131-132) corresponding to a difference between the sink current 131 and the source current 132 starts to flow through the transistors M51 and M52 as the third current IB1, the transistor M53 causes the fourth current IB2 (β×IB1) corresponding to a mirror ratio β of the current mirror CM2 to flow from the power supply voltage node toward the internal node n32. As a result, the third current IB1 becomes a differential current (IB0−IB2) obtained by subtracting the fourth current IB2 from the constant current IB0.

By such a negative feedback action, the third current IB1 flowing through the transistors M51 and M52 is regulated to a current value for clamping the output signal HS appearing at the internal node n32 to an appropriate level.

It should be noted that, in the case where the number of stages of the MOS diodes connected in series between the power supply voltage node and the internal node n32 is n (n=2 in the drawing) and each gate-source voltage is Vgs, Vclp2=n×Vgs is established.

The third current IB1 (IB0/(1+flowing through the transistors M51 and M52 depends on the constant current IB0 (131-132) and the mirror ratio β of the current mirror CM2. Here, in the case where the current sources CS31 and CS32 are formed of the depletion-type transistors dep1 and dep2, respectively, the sink current 131 and the source current 132 have positive temperature characteristics. That is, the constant current IB0 (131-132) increases as the temperature increases, and decreases as the temperature decreases. On the other hand, the gate-source voltages Vgs of the enhancement-type transistors M51 and M52 have negative temperature characteristics. That is, the gate-source voltage Vgs decreases as the temperature increases, and increases as the temperature decreases.

Therefore, by adjusting sizes of the respective transistors dep1 and dep2 and the respective transistors M51 to M53 and appropriately selecting the mirror ratio β of the current mirror CM2, it is possible to realize the second clamp voltage Vclp2 (for example, 3 V) independent of the temperature.

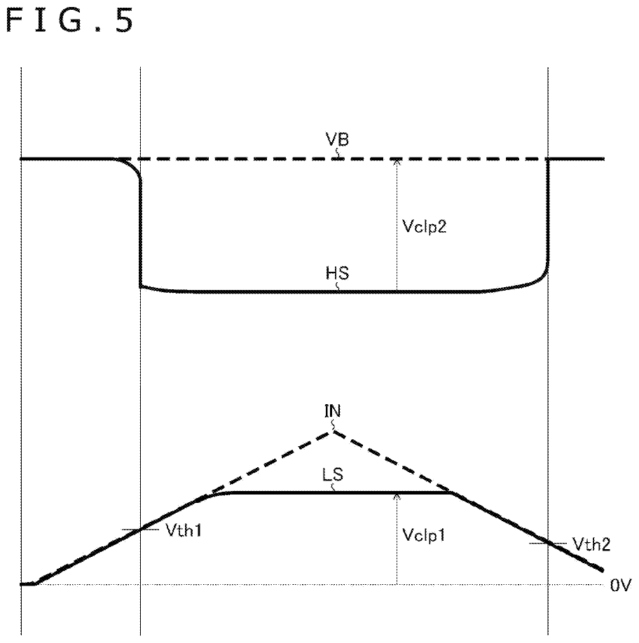

FIG. 5 is a diagram depicting an operation example by the input circuit 22 of the first embodiment. It should be noted that the output signal HS (solid line) and the power supply voltage VB (broken line) are depicted in an upper part of the drawing. On the other hand, the output signal LS (solid line) and the input signal IN (broken line) are depicted in a lower part of the drawing.

As depicted in the lower part of the drawing, the output signal LS rises according to a rise of the input signal IN, and decreases according to a decrease of the input signal IN. However, the high level of the output signal LS is limited to the first clamp voltage Vclp1 or less by the operation of the clamper CLP1.

On the other hand, as depicted in the upper part of the drawing, the output signal HS becomes a low level (for example, VB−Vclp2) when the input signal IN is at a high level (>Vth1), and becomes a high level (for example, VB) when the input signal IN is at a low level (<Vth2). That is, the output signal HS becomes a logical inversion signal of the input signal IN. It should be noted that the low level of the output signal HS is limited to a voltage value, which is obtained by subtracting the second clamp voltage Vclp2 from the power supply voltage VB, or more (for example, VB−3 V or more).

### <Input Circuit (Second Embodiment)>

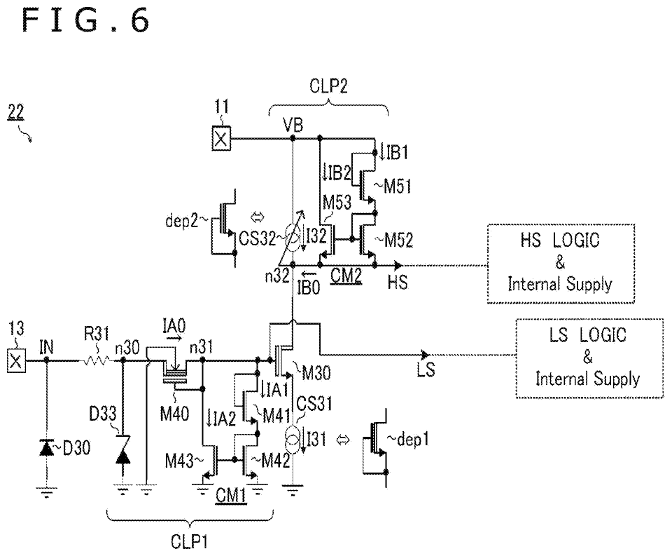

FIG. 6 is a diagram depicting an input circuit 22 according to a second embodiment. The input circuit 22 of the present embodiment includes a Zener diode D33 in place of (or in addition to) the above-described resistor R32 on the basis of the first embodiment (FIG. 4) described above. Accordingly, the constitutional elements described above are denoted by the same reference symbols as those in FIG. 4 to omit the duplicated description, and the following description will focus on characteristic parts of the present embodiment.

A cathode of the Zener diode D33 is connected to the internal node n30. An anode of the Zener diode D33 is connected to a reference voltage node (for example, a ground terminal). The Zener diode D33 thus connected functions as a clamp element for limiting the voltage to be applied to the drain of the transistor M40.

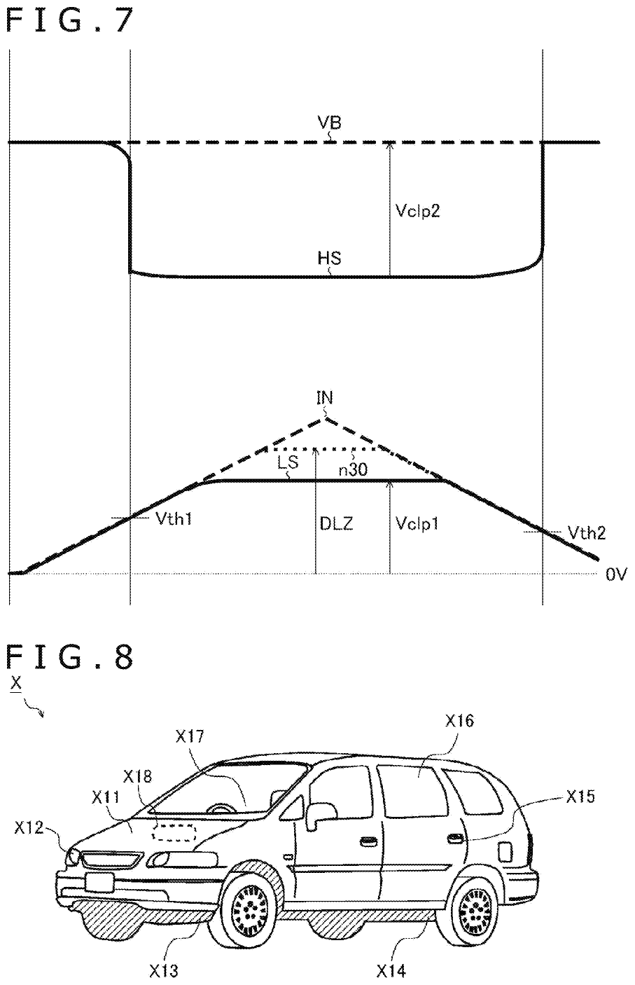

FIG. 7 is a diagram depicting an operation example by the input circuit 22 of the second embodiment. It should be noted that, as in FIG. 5, the output signal HS (solid line) and the power supply voltage VB (broken line) are depicted in an upper part of the drawing. On the other hand, the output signal LS (solid line), the input signal IN (broken line), and the applied voltage (small broken line) of the internal node n30 are depicted in a lower part of the drawing.

As depicted in the drawing, by introducing the Zener diode D33, the applied voltage of the internal node n30 is limited to a breakdown voltage DLZ or less (for example, 5 V or less) of the Zener diode D33. Therefore, since the drain-source voltage of the transistor M40 can be suppressed, an element breakdown voltage required for the transistor M40 can be lowered.

### <Application to Vehicle>

FIG. 8 is an external view for depicting a configuration example of a vehicle X. The vehicle X of the present configuration example is equipped with a battery (not depicted in the drawing) and various electronic apparatuses X11 to X18 that are operated by receiving power supply from the battery.

The vehicle X includes, in addition to an engine vehicle, an electric vehicle (xEV such as a battery electric vehicle (BEV), a hybrid electric vehicle (HEV), a plug-in hybrid electric vehicle/plug-in hybrid vehicle (PHEV/PHV), or a fuel cell electric vehicle/fuel cell vehicle (FCEV/FCV)).

It should be noted that mounting positions of the electronic apparatuses X11 to X18 in the drawing may be different from actual ones for convenience of illustration.

The electronic apparatus X11 is an electronic control unit that performs control related to an engine (injection control, electronic throttle control, idling control, oxygen sensor heater control, auto-cruise control, and other control), or control related to a motor (torque control, power regeneration control, and other control).

The electronic apparatus X12 is a lamp control unit that performs turning on/off control of a high intensity discharged lamp (HID), a daytime running lamp (DRL), and other lamps.

The electronic apparatus X13 is a transmission control unit that performs control related to a transmission.

The electronic apparatus X14 is a braking unit that performs control related to the motion of the vehicle X (anti-lock brake system (ABS) control, electric power steering (EPS) control, electronic suspension control, and other control).

The electronic apparatus X15 is a security control unit that performs driving control of a door lock, a crime prevention alarm, and other systems.

The electronic apparatus X16 is an electronic apparatus that is incorporated in the vehicle X when being shipped from a factory as standard equipment or manufacturer optional equipment, such as a wiper, an electric door mirror, a power window, a damper (shock absorber), an electric sunroof, and an electric seat.

The electronic apparatus X17 is an electronic apparatus that is optionally mounted in the vehicle X as user optional equipment such as an on-vehicle audio/visual (A/V) apparatus, a car navigation system, and an electronic toll collection system (ETC).

The electronic apparatus X18 is an electronic apparatus that includes a high breakdown voltage motor for an on-vehicle blower, an oil pump, a water pump, a battery cooling fan, or other units.

It should be noted that the electronic apparatus A described above can be understood as the electronic apparatuses X11 to X18. That is, the semiconductor device 1 described above can be incorporated into any of the electronic apparatuses X11 to X18.

### <Summary>

Hereinafter, the various embodiments described above will be comprehensively described.

For example, a clamper disclosed in the present specification has a configuration (first configuration) including a current source that is connected between an external electrode and an internal node and generates a predetermined constant current, a diode having an anode connected to the internal node, and a current mirror that generates a second current corresponding to a first current flowing via the diode and draws the second current from the internal node to a reference voltage node.

It should be noted that the clamper according to the first configuration may have a configuration (second configuration) in which the current mirror includes a first transistor having a gate and a drain connected to a cathode of the diode and a source connected to the reference voltage node, and a second transistor having a gate connected to the gate of the first transistor, a drain connected to the internal node, and a source connected to the reference voltage node.

In addition, the clamper according to the first or second configuration may have a configuration (third configuration) in which the current source is a depletion-type transistor that short-circuits between its gate and source.

In addition, the clamper according to any one of the first to third configurations may have a configuration (fourth configuration) further including a Zener diode that limits a voltage to be applied to the current source.

In addition, for example, a clamper disclosed in the present specification has a configuration (fifth configuration) including a first current source that is connected between an internal node and a reference voltage node and generates a predetermined sink current, a second current source that is connected between a power supply voltage node and the internal node and generates a predetermined source current smaller than the sink current, a diode having an anode connected to the power supply voltage node, and a current mirror that generates a second current corresponding to a first current flowing via the diode and causes the second current to flow from the power supply voltage node to the internal node.

It should be noted that the clamper according to the fifth configuration may have a configuration (sixth configuration) in which the current mirror includes a first transistor having a gate and a drain connected to a cathode of the diode and a source connected to the internal node, and a second transistor having a gate connected to the gate of the first transistor, a drain connected to the power supply voltage node, and a source connected to the internal node.

In addition, the clamper according to the fifth or sixth configuration may have a configuration (seventh configuration) in which the first current source and the second current source are each a depletion-type transistor that short-circuits between its gate and source.

In addition, the clamper according to any one of the fifth to seventh configurations may have a configuration (eighth configuration) in which the second current source switches a magnitude of the source current according to an output signal appearing at the internal node.

In addition, for example, an input circuit disclosed in the present specification has a configuration (ninth configuration) including a transistor having a gate connected to a first internal node and a drain connected to a second internal node, a first clamper that limits a potential difference between the first internal node and a reference voltage node to a first clamp voltage or less, and a second clamper that limits a potential difference between a power supply voltage node and the second internal node to a second clamp voltage or less. The first clamper includes a current source that is connected between an external electrode and the first internal node and generates a predetermined constant current, a first diode having an anode connected to the first internal node, and a first current mirror that generates a second current corresponding to a first current flowing via the first diode and draws the second current from the first internal node to the reference voltage node. The second clamper includes a first current source that is connected between the second internal node and the reference voltage node and generates a predetermined sink current, a second current source that is connected between the power supply voltage node and the second internal node and generates a predetermined source current smaller than the sink current, a second diode having an anode connected to the power supply voltage node, and a second current mirror that generates a fourth current corresponding to a third current flowing via the second diode and causes the fourth current to flow from the power supply voltage node to the second internal node.

In addition, for example, a semiconductor device disclosed in the present specification has a configuration (tenth configuration) including the clamper according to any one of the first to eighth configurations or the input circuit according to the ninth configuration.

### Other Modified Examples

It should be noted that, in addition to the above embodiments, various changes can be added to various technical features disclosed in the present specification without departing from the spirit of the technical creation thereof. For example, mutual substitution of a bipolar transistor and a MOS field effect transistor or logic level inversion of various signals are optional. That is, the above embodiments should be considered exemplary in all respects and not restrictive, and it should be understood that the technical scope of the present technology is defined by the claims and includes all changes falling within the meaning and scope equivalent to the claims.

What is claimed is:

1. A clamper comprising:
a current source that is connected between an external electrode and an internal node and generates a predetermined constant current;
a diode having an anode connected to the internal node; and
a current mirror that generates a second current corresponding to a first current flowing via the diode and draws the second current from the internal node to a reference voltage node.

2. The clamper according to claim 1, wherein the current mirror includes
a first transistor having a gate and a drain connected to a cathode of the diode and a source connected to the reference voltage node, and
a second transistor having a gate connected to the gate of the first transistor, a drain connected to the internal node, and a source connected to the reference voltage node.

3. The clamper according to claim 1, wherein the current source is a depletion-type transistor that short-circuits between its gate and source.

4. The clamper according to claim 1, further comprising:
a Zener diode that limits a voltage to be applied to the current source.

5. A clamper comprising:
a first current source that is connected between an internal node and a reference voltage node and generates a predetermined sink current;
a second current source that is connected between a power supply voltage node and the internal node and generates a predetermined source current smaller than the sink current;
a diode having an anode connected to the power supply voltage node; and
a current mirror that generates a second current corresponding to a first current flowing via the diode and causes the second current to flow from the power supply voltage node to the internal node.

6. The clamper according to claim 5, wherein the current mirror includes
a first transistor having a gate and a drain connected to a cathode of the diode and a source connected to the internal node, and
a second transistor having a gate connected to the gate of the first transistor, a drain connected to the power supply voltage node, and a source connected to the internal node.

7. The clamper according to claim 5, wherein the first current source and the second current source are each a depletion-type transistor that short-circuits between its gate and source.

8. The clamper according to claim 5, wherein the second current source switches a magnitude of the source current according to an output signal appearing at the internal node.

9. An input circuit comprising:
a transistor having a gate connected to a first internal node and a drain connected to a second internal node;
a first clamper that limits a potential difference between the first internal node and a reference voltage node to a first clamp voltage or less; and
a second clamper that limits a potential difference between a power supply voltage node and the second internal node to a second clamp voltage or less,
wherein the first clamper includes
a current source that is connected between an external electrode and the first internal node and generates a predetermined constant current,
a first diode having an anode connected to the first internal node, and
a first current mirror that generates a second current corresponding to a first current flowing via the first diode and draws the second current from the first internal node to the reference voltage node, and
the second clamper includes
a first current source that is connected between the second internal node and the reference voltage node and generates a predetermined sink current,
a second current source that is connected between the power supply voltage node and the second internal node and generates a predetermined source current smaller than the sink current,
a second diode having an anode connected to the power supply voltage node, and
a second current mirror that generates a fourth current corresponding to a third current flowing via the second diode and causes the fourth current to flow from the power supply voltage node to the second internal node.

10. A semiconductor device comprising:
the clamper according to claim 1.

11. A semiconductor device comprising:
the input circuit according to claim 9.
